(19) United States
(12) Patent Application Publication
(10) Pub. No.: US 2024/0321800 A1
(43) Pub. Date: Sep. 26, 2024

(54) DISPLAY DEVICE

(71) Applicant: E Ink Holdings Inc., Hsinchu (TW)

(72) Inventors: Wenchuan Wang, Hsinchu (TW); Kuang-Heng Liang, Hsinchu (TW); Wen-Yu Kuo, Hsinchu (TW); Yen-Ze Huang, Hsinchu (TW); Jen-Shiun Huang, Hsinchu (TW)

(73) Assignee: E Ink Holdings Inc., Hsinchu (TW)

(21) Appl. No.: 18/444,786

(22) Filed: Feb. 19, 2024

Related U.S. Application Data
(60) Provisional application No. 63/453,169, filed on Mar. 20, 2023.

(51) Int. Cl. H01L 23/00; G02B 26/00; G02F 1/167; G02F 1/1676; G02F 1/1677

(52) U.S. Cl. CPC H01L 24/16; G02B 26/005; G02F 1/1676; G02F 1/1677; H01L 24/05; H01L 24/13; G02F 1/167; H01L 24/14; H01L 2224/05541; H01L 2224/05555; H01L 2224/13007; H01L 2224/13013; H01L 2224/13014; H01L 2224/13139; H01L 2224/13147; H01L 2224/14051; H01L 2224/14155; H01L 2224/16237; H01L 2924/1426

(57) ABSTRACT

A display device includes a driving circuit substrate, a display layer, an opposite substrate, and a conducting structure. The driving circuit substrate includes a first substrate and a driving circuit layer disposed on the first substrate. The driving circuit layer includes a display region, a peripheral region at the periphery of the display region, and a conducting pad located between the peripheral region and an edge of the first substrate. The opposite substrate includes a second substrate and an opposite electrode layer disposed on the second substrate. The display layer is located between the opposite electrode layer and the driving circuit layer. A conductive member of the conducting structure is connected between the conducting pad and the opposite electrode layer. The conducting structure has a first width. The peripheral region has a second width. The first width is less than or equal to 2.5 times the second width.

### CROSS-REFERENCE TO RELATED APPLICATION

This application claims the priority benefit of U.S. provisional application Ser. No. 63/453,169, filed on Mar. 20, 2023. The entirety of the above-mentioned patent application is hereby incorporated by reference herein and made a part of this specification.

### BACKGROUND

### Technical Field

The disclosure relates to an electronic device, and more particularly to a display device.

### Description of Related Art

Display devices have become an integral part of various electronic products. The design of the slim border has always been one of the important research and development directions of the display device. In the design of the slim border, in addition to the layout of the circuit needs to be considered, the planning of the assembly is also an important part.

### SUMMARY

The disclosure provides a display device, which facilitates the realization of a structure with a slim border.

The display device of the disclosure includes a driving circuit substrate, a display layer, an opposite substrate, and a conducting structure. The driving circuit substrate includes a first substrate and a driving circuit layer disposed on the first substrate. The driving circuit layer includes a display region, a peripheral region, and a conducting pad. The peripheral region is disposed at the periphery of the display region, and the conducting pad is located between the peripheral region and an edge of the first substrate. The display layer is disposed on the driving circuit substrate. The opposite substrate includes a second substrate and an opposite electrode layer disposed on the second substrate. The display layer is located between the opposite electrode layer and the driving circuit layer. The conducting structure includes a conductive member. The conductive member is connected between the conducting pad and the opposite electrode layer. The conducting structure has a first width in a prescribed direction, the peripheral region has a second width in the prescribed direction, and the first width is less than or equal to 2.5 times the second width.

In an embodiment of the disclosure, the above-mentioned prescribed direction is parallel to a side length direction of the display region.

In an embodiment of the disclosure, the above-mentioned conducting structure includes a conducting hole accommodating the conductive member, and the conducting hole penetrates through the display layer. The first width of the conducting structure is the width of the conducting hole in the prescribed direction. The display layer laterally surrounds the conducting hole. An edge of the display layer is recessed to form the conducting hole. The maximum recess depth of the edge of the display layer in the prescribed direction is the first width.

In an embodiment of the disclosure, the above-mentioned display layer is driven by the driving circuit layer and displays merely a single color in the peripheral region.

In an embodiment of the disclosure, the above-mentioned opposite electrode layer has a protruding portion that is tongue-shaped and protrudes from the edge of the display layer toward the conducting pad, and the protruding portion and the driving circuit layer are electrically connected through another conducting structure.

The display device of the disclosure includes a driving circuit substrate, a display layer, an opposite substrate, and a conductive member. The driving circuit substrate includes a first substrate and a driving circuit layer disposed on the first substrate. The driving circuit layer includes a display region, a common voltage region, and a conducting pad. The common voltage region is disposed at the periphery of the display region, and the conducting pad is located on the common voltage region and electrically connected to the common voltage region. The display layer is disposed on the driving circuit substrate. The opposite substrate includes a second substrate and an opposite electrode layer disposed on the second substrate. The display layer is located between the opposite electrode layer and the driving circuit layer. The conductive member is connected between the conducting pad and the opposite electrode layer.

In an embodiment of the disclosure, the above-mentioned display layer exposes the conducting pad and surrounds the conductive member.

In an embodiment of the disclosure, the above-mentioned display device further includes a protective insulating layer, disposed between a metal conductive layer and a pad conductive layer.

Based on the above, the display device of the embodiment of the disclosure uses a reduced conducting structure and even integrates the conducting structure into the original device area, thereby achieving the design of the slim border.

### BRIEF DESCRIPTION OF THE DRAWINGS

FIG. 1 is a schematic partial top view of a display device according to an embodiment of the disclosure.

FIG. 2 is an enlarged schematic diagram of a local area E1 in FIG. 1.

FIGS. 3 to 6 are partial manufacturing processes of the display device of FIG. 1.

FIG. 7 is a schematic diagram of a display device according to another embodiment of the disclosure.

FIG. 8 is an enlarged schematic diagram of a local area E2 in FIG. 7.

FIG. 9 is a schematic diagram of a display device according to another embodiment of the disclosure.

FIG. 10 is an enlarged schematic diagram of a local area E3 in FIG. 9.

FIG. 11 is a schematic partial top view of a display layer according to another embodiment of the disclosure.

FIG. 12 is a schematic top view of a display device according to another embodiment of the disclosure.

FIG. 13 is a schematic cross-sectional view of the display device of FIG. 12 along a line II-II.

FIG. 14 is a schematic cross-sectional view of the display device of FIG. 12 along a line III-III.

FIG. 15 is a schematic diagram of the display device of FIG. 13 after being bent.

FIG. 16 is a schematic top view of a display device according to another embodiment of the disclosure.

FIG. 17 is a schematic cross-sectional view of the display device of FIG. 16 along a line IV-IV.

FIG. 18 is a schematic diagram of a display layer and a common voltage region in a display device according to an embodiment of the disclosure.

FIG. 19 is a schematic diagram of the display layer and the common voltage region of FIG. 18 being applied to a display device.

FIG. 20 is a schematic diagram of a display layer and a common voltage region in a display device according to an embodiment of the disclosure.

### DESCRIPTION OF THE EMBODIMENTS

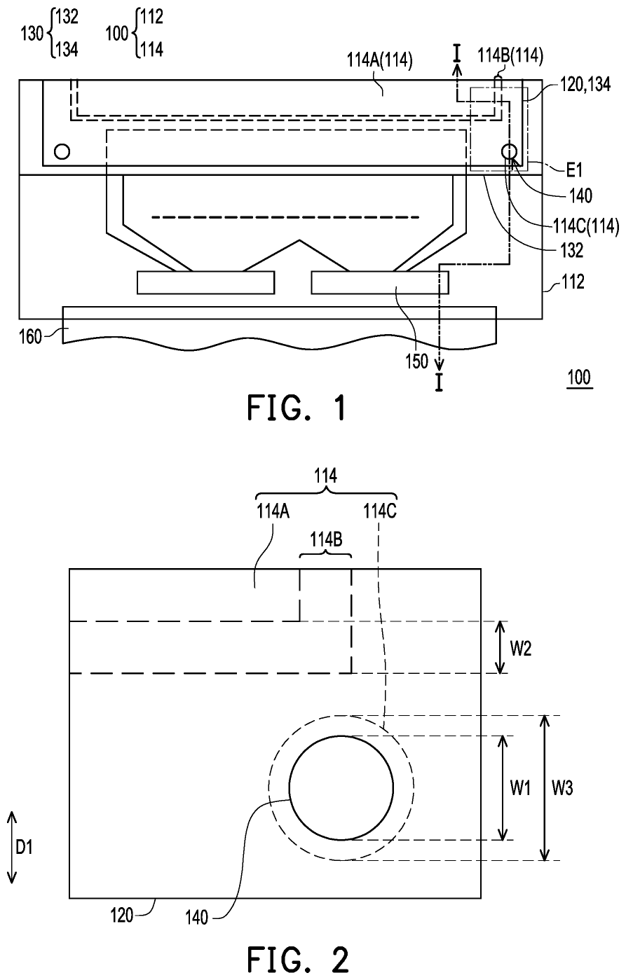

FIG. 1 is a schematic partial top view of a display device according to an embodiment of the disclosure. A display device 100 of FIG. 1 includes a driving circuit substrate 110, a display layer 120, an opposite substrate 130, and a conducting structure 140. The driving circuit substrate 110 includes a first substrate 112 and a driving circuit layer 114. The driving circuit layer 114 includes a display region 114A, a peripheral region 114B, and a conducting pad 114C. The peripheral region 114B is disposed at the periphery of the display region 114A, and the conducting pad 114C is located between the peripheral region 114B and an edge of the first substrate 112. The display layer 120 is disposed on the driving circuit substrate 110. The opposite substrate 130 includes a second substrate 132 and an opposite electrode layer 134 disposed on the second substrate 132, and the display layer 120 is located between the opposite electrode layer 134 and the driving circuit layer 114. In the embodiment, the outlines of the second substrate 132 and the opposite electrode layer 134 are overlapped, so the second substrate 132 and the opposite electrode layer 134 are marked at the same position, but are not limited thereto.

In the embodiment, the display layer 120 is, for example, an electronic paper display element, which includes an electrophoretic display element and an electrowetting display element, and the display medium may be encapsulated therein by means such as microcups and microcapsules. The display layer 120 is driven by the electric field formed by the driving circuit layer 114 and the opposite electrode layer 134 to display a desired image. In some embodiments, the driving electric field provided by the driving circuit layer 114 in the display region 114A may make the display layer 120 present image information. In some embodiments, the driving circuit layer 114 may provide a driving electric field in the peripheral region 114B, and the display layer 120 is driven by the driving circuit layer 114 and displays merely a single color in the peripheral region 114B. Therefore, the peripheral region 114B may be configured to present a border pattern, but not to present a display image. In some embodiments, the driving circuit layer 114 does not need to provide a driving electric field in the peripheral region 114B, and the peripheral region 114B may be provided with monochrome light-shielding strips or similar structures to present a border pattern surrounding the display region 114A. In other words, the peripheral region 114B surrounding the display region 114A is configured to present a border pattern of a single color (e.g., black), and is not configured to display an image. In addition, the display layer 120 may extend to the peripheral region 114B, but the peripheral region 114B may selectively not use the display layer 120 and present a border pattern in other ways.

FIG. 2 is an enlarged schematic diagram of a local area E1 in FIG. 1. As shown in FIGS. 1 and 2, the conducting structure 140 has a first width W1 in a prescribed direction D1, the peripheral region 114B has a second width W2 in the prescribed direction D1, and the first width W1 is less than or equal to 2.5 times the second width W2. The second width W2 may be understood as the minimum distance between the peripheral region 114B and the display region 114A in the prescribed direction D1. In some embodiments, the prescribed direction D1 may be parallel to the side length direction of the display region 114A. In some embodiments, the conducting pad 114C has a third width W3 in the prescribed direction D1. In some embodiments, the third width W3 may be greater than the first width W1. In other words, the conducting structure 140 for electrically conducting the conducting pad 114C with the opposite electrode layer 134 may have a smaller size than the conducting pad 114C, thereby facilitating the reduction in the border width of the display device 100. In some embodiments, the first width W1 may be less than 2 millimeters (mm), such as 1-1.5 mm, 1.2 mm, etc. In some embodiments, the second width W2 is, for example, 0.6 mm, but is not limited thereto.

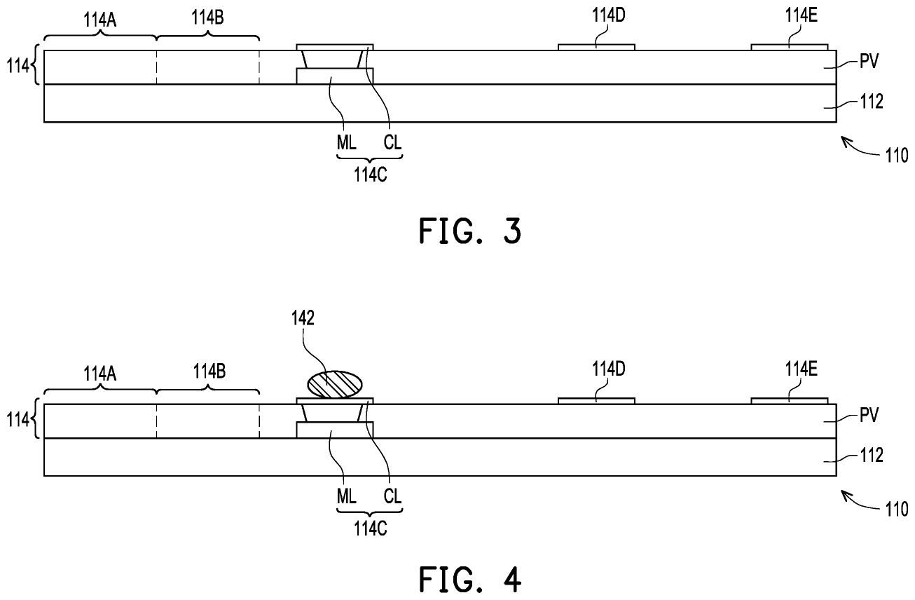

FIGS. 3 to 6 are partial manufacturing processes of the display device of FIG. 1, and FIGS. 3 to 6 may correspond to the cross section of a line I-I in FIG. 1. In FIG. 3, the driving circuit substrate 110 includes the first substrate 112 and the driving circuit layer 114. The first substrate 112 may have certain mechanical properties to support elements formed thereon. The first substrate 112 may be a rigid substrate or a flexible substrate. The driving circuit layer 114 is disposed on the first substrate 112. The driving circuit layer 114 may be composed of multiple conductive layers, multiple insulating layers, and one or more semiconductor layers, so as to realize the required driving circuit. According to the circuit composed of multiple conductive layers, multiple insulating layers, and one or more semiconductor layers, the driving circuit layer 114 may include the display region 114A, the peripheral region 114B, the conducting pad 114C, a driving circuit pad 114D, and a circuit board pad 114E. To simplify the drawing, the specific structures of the display region 114A and the peripheral region 114B are omitted, but the specific structures of the display region 114A and the peripheral region 114B may be implemented according to the common driving circuit structure for driving the display layer 120 in the art. For example, the specific structures of the display region 114A and the peripheral region 114B may include multiple active devices, multiple scanning lines, multiple data lines, and/or multiple storage capacitors arranged in an array. In addition, FIG. 3 merely schematically presents a possible implementation of the conducting pad 114C, the driving circuit pad 114D, and the circuit board pad 114E, but the actual structural design does not have to be limited thereto.

As shown in FIG. 3, the conducting pad 114C may include a metal conductive layer ML and a pad conductive layer CL, and a protective insulating layer PV is disposed between the metal conductive layer ML and the pad conductive layer CL. The metal conductive layer ML is located between the protective insulating layer PV and the first substrate 112, the pad conductive layer CL is disposed on the protective insulating layer PV, and the protective insulating layer PV has a through hole V1 to allow the pad conductive layer CL to be connected through the through hole V1 to the metal conductive layer ML. The driving circuit pad 114D and the circuit board pad 114E may be the same layer as the pad conductive layer CL. In some embodiments, the protective insulating layer PV may include one or more insulating layers. In some embodiments, the metal conductive layer ML may extend outward to be connected to other conductive elements, so the width of the so-called conducting pad 114C in the disclosure may be understood as the width of the pad conductive layer CL. In another embodiment of the disclosure, the width of the pad conductive layer CL may be the same as the width of the through hole V1, and the pad conductive layer CL is merely disposed in the through hole V1 and is not disposed on the surface of the protective insulating layer PV.

In the step shown in FIG. 4, a conductive member 142 is disposed on the driving circuit substrate 110, and the conductive member 142 overlaps the conducting pad 114C. Specifically, the conductive member 142 may contact the pad conductive layer CL of the conducting pad 114C. The conductive member 142 has good electrical conductivity, and may include conductive elements such as solder, silver glue, copper glue, and the like.

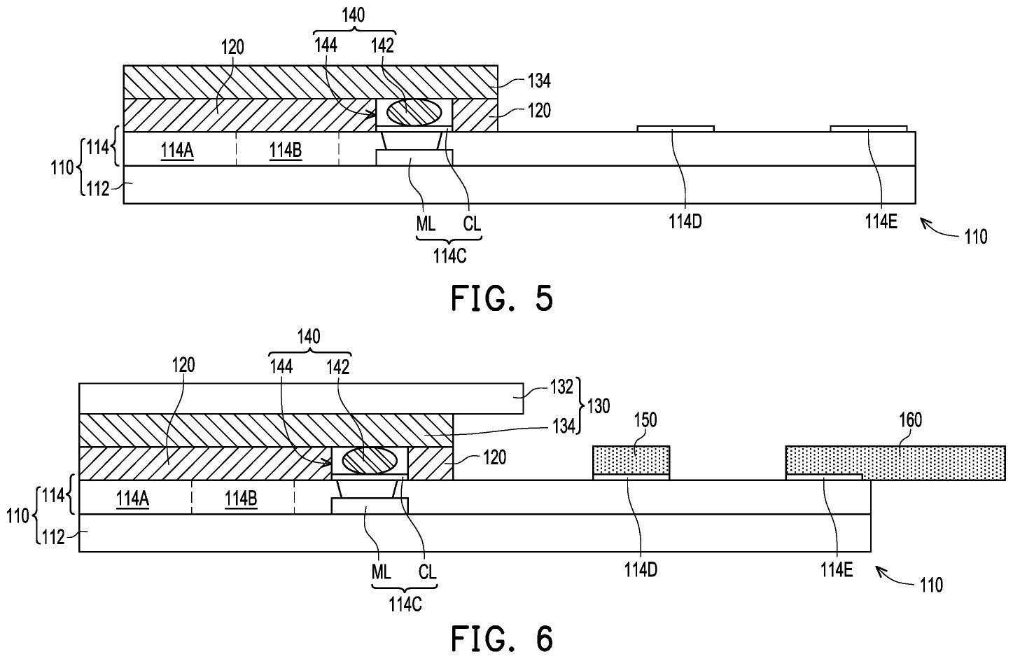

The step shown in FIG. 5 includes attaching the display layer 120 together with the opposite electrode layer 134 to the driving circuit substrate 110. In some embodiments, the display layer 120 and the opposite electrode layer 134 may be attached together in advance, and then attached to the driving circuit substrate 110. In some embodiments, the opposite electrode layer 134 includes a carrier film and a transparent conductive layer fabricated on the carrier film. The carrier film may include a plastic film such as a PET film, and the transparent conductive layer may include a conductive layer of metal oxide (such as indium tin oxide, indium zinc oxide, etc.), but not limited thereto. In addition, the transparent conductive layer in the opposite electrode layer 134 may contact the surface of the display layer 120. The display layer 120 may be a display element having a microcup or microcapsule structure.

The display layer 120 may be pre-processed to have a desired pattern. For example, a part of the display layer 120 may be removed to form a conducting hole 144, so that the conducting hole 144 may expose the opposite electrode layer 134. That is to say, the processing of the display layer 120 may merely remove a part of the display layer 120 while retaining the opposite electrode layer 120. In addition, when the display layer 120 is attached to the driving circuit substrate 110, the conducting hole 144 may be aligned with the conductive member 142 to allow the conductive member 142 to contact the opposite electrode layer 134 through the conducting hole 144.

Next, the step in FIG. 6 includes attaching the second substrate 132 to the driving circuit substrate 110 to complete the display device 100. The second substrate 132 may have properties of blocking moisture and being transparent to at least visible light. Therefore, the second substrate 132 may support the display device 100 and also protect the display device 100. The size of the second substrate 132 may be larger than the display layer 120 and the opposite electrode layer 134, but is not limited thereto.

Referring to FIGS. 1 and 6, the display device 100 may include the driving circuit substrate 110, the display layer 120, the opposite substrate 130, and the conducting structure 140. The driving circuit substrate 110 includes the first substrate 112 and the driving circuit layer 114. The display layer 120 is disposed on the driving circuit substrate 110. The opposite substrate 130 includes the second substrate 132 and the opposite electrode layer 134 disposed on the second substrate 132. The display layer 120 is located between the opposite electrode layer 134 and the driving circuit layer 114. The conducting structure 140 includes the conductive member 142, and the conductive member 142 is connected between the conducting pad 114C and the opposite electrode layer 134. In addition, the conducting structure 140 further includes the conducting hole 144 penetrating through the display layer 120 and accommodating the conductive member 142.

In some embodiments, the size of the conductive member 142 may be designed according to the corresponding conducting hole 144 thereof. For example, the size of the conductive member 142 may be smaller than the size of the conducting hole 144 to ensure the smooth completion of the fabrication step of FIG. 5. In some embodiments, the first width W1 (marked in FIG. 2) of the conducting structure 140 may be understood as the width of the conducting hole 144 in the prescribed direction D1. The conducting hole 144 may be defined, for example, by the removed portion of the display layer 120, so the display layer 120 may laterally surround the conducting hole 144.

In addition, as shown in FIGS. 1 and 6, the display device 100 may further include a driving circuit 150 and a circuit board 160 that are bonded to the driving circuit substrate 110. The circuit board 160 may include a flexible circuit board, and the driving circuit 150 may be a packaged semiconductor chip, but not limited thereto. The driving circuit 150 and the circuit board 160 may be respectively bonded to the driving circuit pad 114D and the circuit board pad 114E in the driving circuit layer 114 on the driving circuit substrate 110. In some embodiments, the first substrate 112 of the driving circuit substrate 110 may be flexible, and the part of the driving circuit substrate 110 on which the driving circuit 150 is disposed may be bent and disposed on the back side of the display region 114A. In this way, when a user uses the display device, the display region 114A is located between the user and the driving circuit 150. However, the disclosure is not limited thereto.

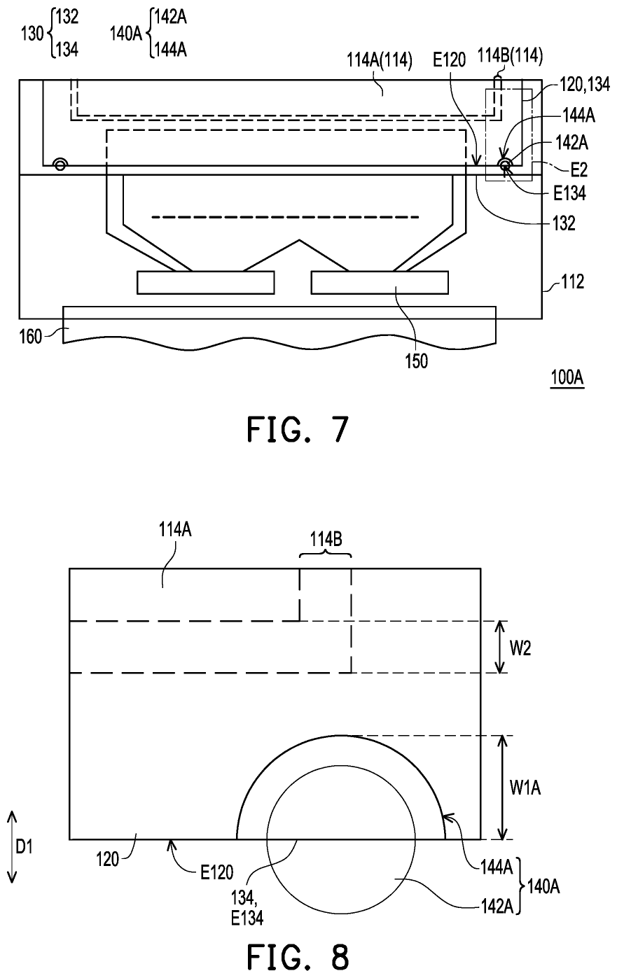

FIG. 7 is a schematic diagram of a display device according to another embodiment of the disclosure. A display device 100A of FIG. 7 is substantially similar to the display device 100 of FIG. 1, and the same reference numerals in the two embodiments are used to denote the same elements. The display device 100A of FIG. 7 may include the driving circuit substrate 110, the display layer 120, the opposite substrate 130, and a conducting structure 140A. For the driving circuit substrate 110, the display layer 120 and the opposite substrate 130, reference may be made to FIG. 1 and related descriptions thereof, and the descriptions are not repeated. The main difference between the embodiment and the embodiment of FIG. 1 lies in the structural design of the conducting structure 140A.

In the display device 100A of FIG. 7, the conducting structure 140A includes a conductive member 142A and a conducting hole 144A. As shown in FIG. 7, an edge E120 of the display layer 120 is recessed to form the conducting hole 144A of the embodiment. In some embodiments, the conducting hole 144A is a semi-circular or semi-elliptical open hole. For example, the edge of the display layer 120 may define the outline of the conducting hole 144A, but the outline is not a closed pattern. Therefore, the display layer 120 laterally surrounds the conducting hole 144A but does not enclose a closed pattern. The conducting hole 144A may accommodate the conductive member 142A, and the conductive member 142A may exceed the size of the conducting hole 144A.

FIG. 8 is an enlarged schematic diagram of a local area E2 in FIG. 7. As shown in FIGS. 7 and 8, the conducting structure 140A has a first width W1A in the prescribed direction D1, the peripheral region 114B has the second width W2 in the prescribed direction D1, and the first width W1A is less than or equal to 2.5 times the second width W2. In some embodiments, the first width W1A may be less than 2 mm, such as 1-1.5 mm, 1.2 mm, etc. In some embodiments, the second width W2 is, for example, 0.6 mm, but is not limited thereto. Since the edge E120 of the display layer 120 is recessed to form the conducting hole 144A, the maximum recess depth of the edge E120 of the display layer 120 in the prescribed direction D1 is the first width W1A. The conductive member 142A may exceed the size of the conducting hole 144A in the prescribed direction D1, and specifically, may exceed the edge E120 of the display layer 120 in the prescribed direction D1, but not limited thereto.

In some embodiments, an edge E134 of the opposite electrode layer 134 has substantially the same outline as the edge E134 of the display layer 120. However, the portion of the edge E134 of the display layer 120 where the conducting hole 144A is formed due to partial removal is different from the outline of the opposite electrode layer 134. Specifically, a part of the opposite electrode layer 134 overlaps the conducting hole 144A, and the conductive member 142A may contact the opposite electrode layer 134 exposed by the conducting hole 144A through the conducting hole 144A. The conducting hole 144A is a structure recessed by the edge E120 of the display layer 120, so the conducting hole 144A is substantially partially surrounded laterally by the display layer 120. Alternatively, the conducting hole 144A may be regarded as a structure formed by a part of the edge E120 of the display layer 120.

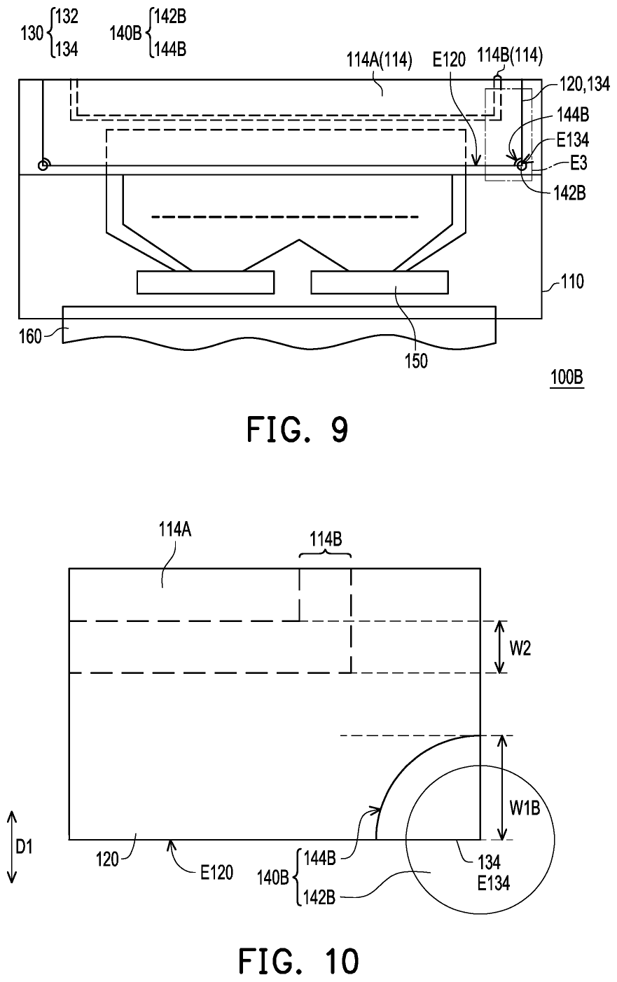

FIG. 9 is a schematic diagram of a display device according to another embodiment of the disclosure. A display device 100B of FIG. 9 is substantially similar to the display device 100 of FIG. 1, and the same reference numerals in the two embodiments are used to denote the same elements. The display device 100B of FIG. 9 may include the driving circuit substrate 110, the display layer 120, the opposite substrate 130, and a conducting structure 140B. For the driving circuit substrate 110, the display layer 120 and the opposite substrate 130, reference may be made to FIG. 1 and related descriptions thereof, and the descriptions are not repeated. The main difference between the embodiment and the embodiment of FIG. 1 lies in the structural design of the conducting structure 140B. In the display device 100B of FIG. 9, the conducting structure 140B includes a conductive member 142B and a conducting hole 144B. As shown in FIG. 9, the edge E120 of the display layer 120 is recessed to form the conducting hole 144B of the embodiment.

FIG. 10 is an enlarged schematic diagram of a local area E3 in FIG. 9. As shown in FIGS. 9 and 10, the conducting structure 140B is located at the corner of the display layer 120. The conducting structure 140B has a first width W1B in the prescribed direction D1, the peripheral region 114B has the second width W2 in the prescribed direction D1, and the first width W1B is less than or equal to 2.5 times the second width W2. Since the edge E120 of the display layer 120 is recessed to form the conducting hole 144B, the maximum recess depth of the edge E120 of the display layer 120 in the prescribed direction D1 is the first width W1B. The conductive member 142B may exceed the size of the conducting hole 144B in the prescribed direction D1, and specifically, may exceed the edge E120 of the display layer 120 in the prescribed direction D1, but not limited thereto. In some embodiments, the first width W1B may be less than 2 mm, such as 1-1.5 mm, 1.2 mm, etc. In some embodiments, the second width W2 is, for example, 0.6 mm, but is not limited thereto.

The edge E134 of the opposite electrode layer 134 and the edge E120 of the display layer 120 may overlap or be aligned with each other except at the conducting hole 144B, but not limited thereto. Therefore, the opposite electrode layer 134 may contact the conductive member 142B at the conducting hole 144B, so as to realize the required electrical connection. The size of the conductive member 142B may be larger than the conducting hole 144B and partially exposed outside the opposite electrode layer 134, but is not limited thereto.

It may be seen from the display device 100 of FIG. 1, the display device 100A of FIG. 7, and the display device 100B of FIG. 9 that the conducting holes 144, 144A, and 144B have reduced sizes, which facilitates the reduction in the required border width of the display layer 120. In some embodiments, the display device 100 of FIG. 1, the display device 100A of FIG. 7, and the display device 100B of FIG. 9 may meet the application of slim borders. However, the method of forming the conducting holes in the display layer 120 is not limited to the above-mentioned embodiments, and the designer may plan the positions and outlines of the conducting holes according to different requirements.

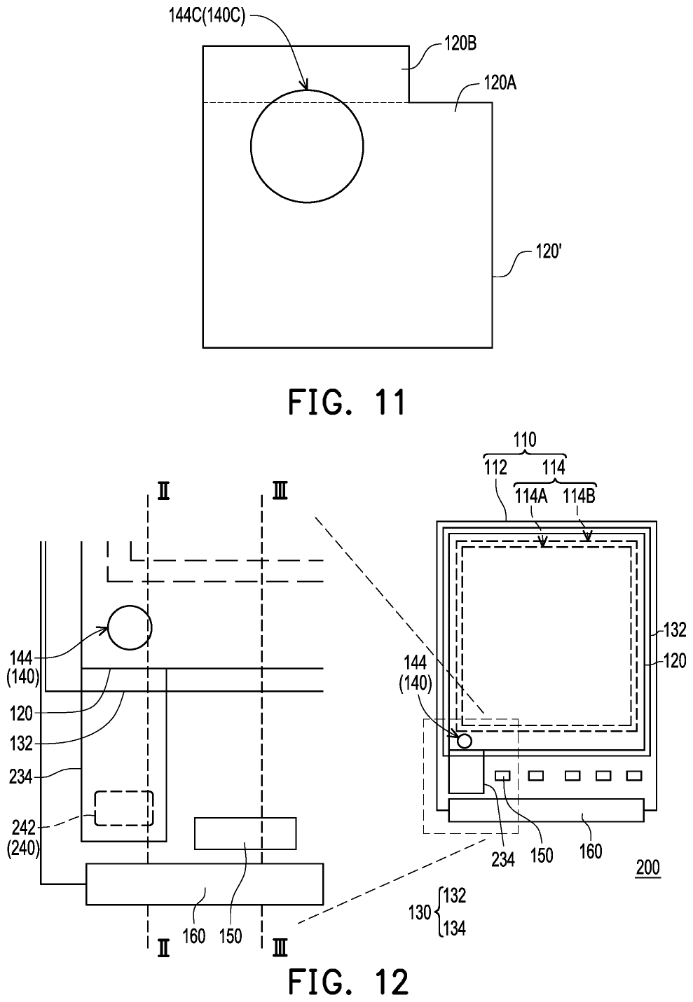

For example, FIG. 11 is a schematic partial top view of a display layer according to another embodiment of the disclosure. In some embodiments, a display layer 120′ of FIG. 11 may be applied in the display device 100 of FIG. 1 to replace the display layer 120 of FIG. 1. As shown in FIG. 11, the display layer 120′ may have a main body portion 120A and an outer convex portion 120B. The main body portion 120A may be a portion having a rectangular outline, and the outer convex portion 120B may be a portion protruding outward from the rectangular outline of the main body portion 120A. The display layer 120′ may be processed and removed a portion to form a conducting hole 144C, which is configured to realize a conducting structure 140C. The conducting hole 144C may be disposed adjacent to the outer convex portion 120B. For example, the conducting hole 144C may be partially located in the main body portion 120A and partially located in the outer convex portion 120B. In this way, the area occupied by the conducting hole 144C in the main body portion 120A may be reduced.

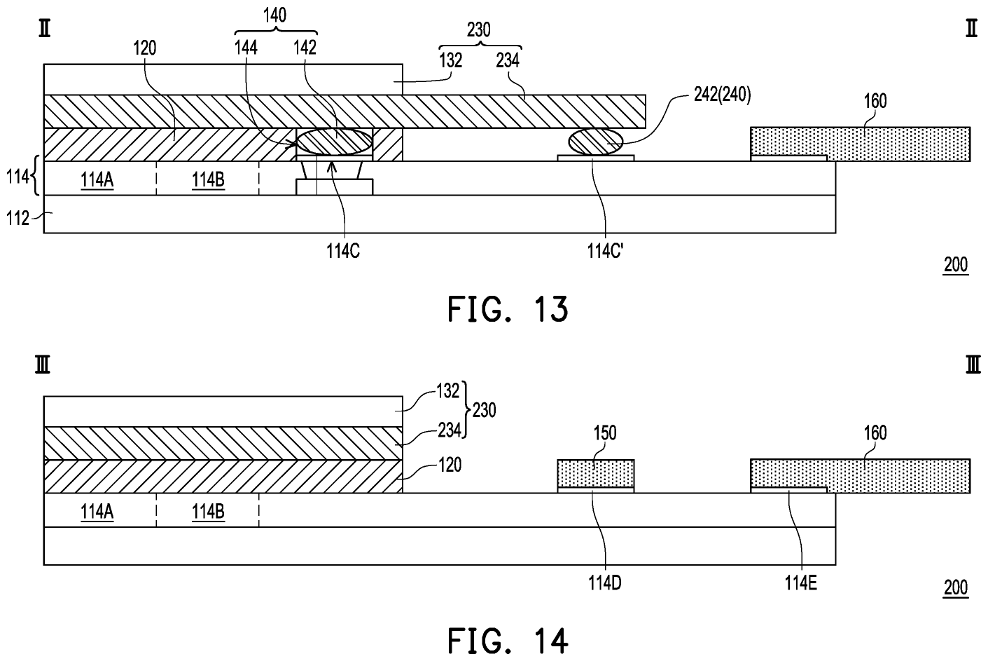

FIG. 12 is a schematic top view of a display device according to another embodiment of the disclosure, FIG. 13 is a schematic cross-sectional view of the display device of FIG. 12 along a line II-II, and FIG. 14 is a schematic cross-sectional view of the display device of FIG. 12 along a line III-III. A display device 200 of FIG. 12 is partially similar to the display device 100 of FIG. 1, and the same reference numerals in the two embodiments are used to denote the same elements. The display device 200 of FIG. 12 may include the driving circuit substrate 110, the display layer 120, an opposite substrate 230, the conducting structure 140, and another conducting structure 240. For the driving circuit substrate 110, the display layer 120 and the conducting structure 140, reference may be made to FIG. 1 and related descriptions thereof, and the descriptions are not repeated. The main difference between the embodiment and the embodiment of FIG. 1 lies in the structural design of the opposite substrate 230 and the another conducting structure 240.

In the embodiment, the driving circuit substrate 110 includes the first substrate 112 and the driving circuit layer 114. The driving circuit layer 114 includes the display region 114A, the peripheral region 114B, the conducting pad 114C, the driving circuit pad 114D, and a conducting pad 114C′. The peripheral region 114B is disposed at the periphery of the display region 114A, and the conducting pad 114C, the driving circuit pad 114D, and the conducting pad 114C′ are located between the peripheral region 114B and the edge of the first substrate 112. The display layer 120 is disposed on the driving circuit substrate 110. The opposite substrate 130 includes a second substrate 132 and an opposite electrode layer 234 disposed on the second substrate 132, and the display layer 120 is located between the opposite electrode layer 234 and the driving circuit layer 114

As shown in FIGS. 12 and 13, the opposite electrode layer 234 exceeds beyond the display layer 120 and at least overlaps the conducting pad 114C′ outside the display layer 120. The conducting structure 240 is disposed on the conducting pad 114C′ and contacts the opposite electrode layer 234. The conducting structure 240 may include a conductive member 242, which is, for example, conductive glue. In addition, the display layer 120 may be selectively processed and form the conducting hole 144 corresponding to the conducting pad 114C. In other embodiments, since the conducting structure 240 is disposed on the conducting pad 114C′, the conducting hole 144 and the conductive member 142 accommodated therein may be omitted, so that the display layer 120 covers the conducting pad 114C. In this way, the display layer 120 may simplify the processing procedure because the disposition of the conducting hole 144 is not required.

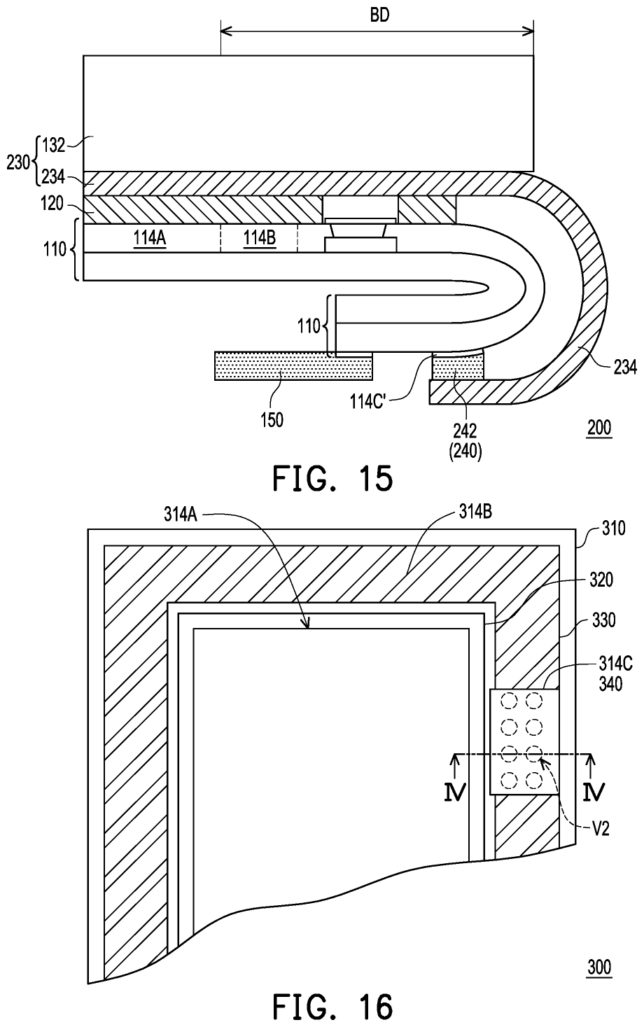

The opposite electrode layer 234 may include a carrier film and a conductive layer fabricated on the carrier film. As shown in FIGS. 12 to 14, the opposite electrode layer 234 has a tongue-shaped protruding portion (as shown in the partially enlarged area of FIG. 12) to protrude from the edge of the display layer 120 toward the conducting pad 114C′. However, the opposite electrode layer 234 and the edge of the display layer 120 may be partially overlapped or aligned, as shown in FIG. 14. In some embodiments, the entire area of the display layer 120 may overlap the opposite electrode layer 234. Specifically, the protruding portion of the opposite electrode layer 234 and the driving circuit layer 114 may be electrically connected through the another conducting structure 240. In some embodiments, the opposite electrode layer 234 and the driving circuit substrate 110 are flexible. Therefore, the opposite electrode layer 234 and the driving circuit substrate 110 may be bent so that the conducting structure 240 is located at the back side of the display region 114A, as shown in FIG. 15. In this way, the border region BD of the display device 200 may be reduced and a slim border structure is realized.

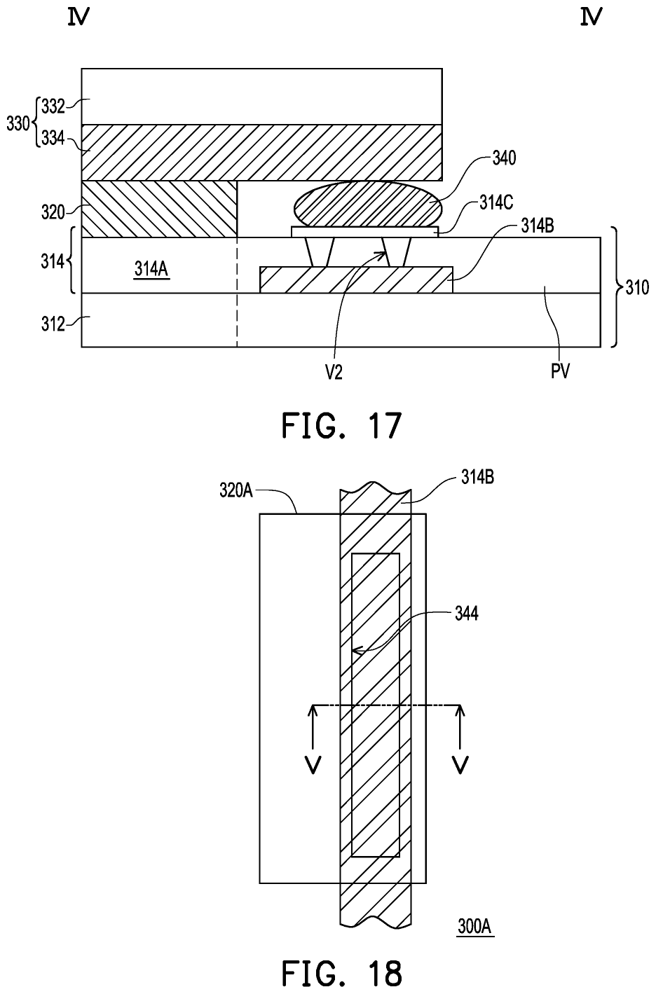

FIG. 16 is a schematic top view of a display device according to another embodiment of the disclosure, and FIG. 17 is a schematic cross-sectional view of the display device of FIG. 16 along a line IV-IV. A display device 300 of FIGS. 16 and 17 includes a driving circuit substrate 310, a display layer 320, an opposite substrate 330, and a conductive member 340. The driving circuit substrate 310 includes a first substrate 312 and a driving circuit layer 314 disposed on the first substrate 312. The display layer 320 is disposed on the driving circuit substrate 310. The opposite substrate 330 includes a second substrate 332 and an opposite electrode layer 334 disposed on the second substrate 332, and the display layer 320 is located between the opposite electrode layer 334 and the driving circuit layer 314. The conductive member 340 is connected between the driving circuit layer 314 and the opposite electrode layer 334.

Specifically, the driving circuit layer 314 includes a display region 314A, a common voltage region 314B, and a conducting pad 314C, the common voltage region 314B is disposed at the periphery of the display region 314A, and the conducting pad 314C is located on the common voltage region 314B and electrically connected to the common voltage region 314B. For example, the protective insulating layer PV may cover the common voltage region 314B, and the conducting pad 314C may contact the common voltage region 314B by penetrating a through hole V2 of the protective insulating layer PV. The conductive member 340 is connected between the conducting pad 314C and the opposite electrode layer 334 to realize the electrical connection between the driving circuit substrate 310 and the opposite substrate 330. The conductive member 340 is located on the common voltage region 314B. Therefore, the display device 300 does not need to reserve a dedicated disposition area for the conductive member 340, which facilitates the reduction in the width of the border. In addition, in some embodiments, the display device 300 may further include a sealant (not shown) disposed between the opposite electrode layer 334 and the driving circuit layer 314, and the sealant may be disposed along the common voltage region 314B so that the sealant and the conductive member 340 surround the display layer 320 together.

In the embodiment, as shown in FIGS. 16 and 17, the display layer 320 may be entirely located in the area surrounded by the common voltage region 314B, so that the display layer 320 exposes the conducting pad 314C, and the conductive member 340 is located outside the display layer 320. However, in other embodiments, the display layer 320 may at least partially overlap the common voltage region 314B, and be processed and have a conducting hole exposing the conducting pad 314C.

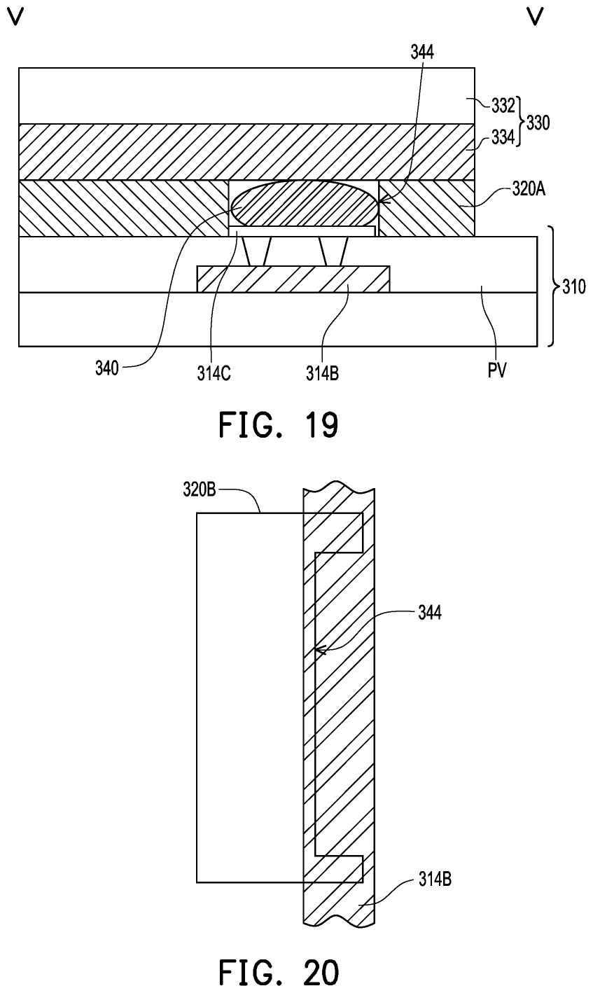

For example, FIG. 18 is a schematic diagram of a display layer and a common voltage region in a display device according to an embodiment of the disclosure, FIG. 19 is a schematic diagram of the display layer and the common voltage region of FIG. 18 being applied to a display device, and FIG. 19 shows a partial section of the display device. The components shown in FIGS. 18 and 19 may serve as alternative implementations of the aforementioned display device 300, so the same reference numerals in the two embodiments are used to describe the same elements. A display device 300A shown in FIGS. 18 and 19 includes the driving circuit substrate 310, a display layer 320A, the opposite substrate 330, and the conductive member 340. The disposition relationship and structure of the driving circuit substrate 310, the opposite substrate 330, and the conductive member 340 are substantially similar to the display device 300 of FIGS. 16 and 17. In the embodiment, the display layer 320A is located between the driving circuit substrate 310 and the opposite substrate 330, and may overlap the common voltage region 314B. In addition, the display layer 320A is processed and has a conducting hole 344 exposing the conducting pad 314C, and the conductive member 340 is located in the conducting hole 344 so that the display layer 320A surrounds the conductive member 340. As shown in FIG. 18, the conducting hole 344 has an elongated outline, and the conducting hole 344 is disposed along the common voltage region 314B. The elongated size of the conducting hole 344 facilitates the increase in the size of the conductive member 340, thereby ensuring the electrical connection between the common electrode layer 334 and the conducting pad 314C. In the embodiment, the conducting hole 344 is disposed inside the display layer 320 and is completely surrounded by the display layer 320, but is not limited thereto. In some embodiments, as shown in FIG. 20, the conducting hole 344 of a display layer 320B may be formed by the edge of the conducting hole 344 being recessed, so the conducting hole 344 has an unclosed outline.

To sum up, the display device of the disclosure uses a small-sized conducting structure to form an electrical connection between two substrates, which may reduce the width of the border. In addition, in the display device of some embodiments of the disclosure, the conducting structure is disposed on the original element, which may realize the electrical connection between the two substrates and may also reduce the width of the border.

What is claimed is:

1. A display device, comprising:
a driving circuit substrate, comprising a first substrate and a driving circuit layer disposed on the first substrate, wherein the driving circuit layer comprises a display region, a peripheral region, and a conducting pad, the peripheral region is disposed at a periphery of the display region, and the conducting pad is located between the peripheral region and an edge of the first substrate;
a display layer, disposed on the driving circuit substrate;
an opposite substrate, comprising a second substrate and an opposite electrode layer disposed on the second substrate, wherein the display layer is located between the opposite electrode layer and the driving circuit layer; and
a conducting structure, comprising a conductive member, which is connected between the conducting pad and the opposite electrode layer, wherein the conducting structure has a first width in a prescribed direction, the peripheral region has a second width in the prescribed direction, and the first width is less than or equal to 2.5 times the second width.

2. The display device according to claim 1, wherein the prescribed direction is parallel to a side length direction of the display region.

3. The display device according to claim 1, wherein the conducting structure comprises a conducting hole accommodating the conductive member, and the conducting hole penetrates through the display layer.

4. The display device according to claim 3, wherein the first width of the conducting structure is a width of the conducting hole in the prescribed direction.

5. The display device according to claim 3, wherein the display layer laterally surrounds the conducting hole.

6. The display device according to claim 3, wherein an edge of the display layer is recessed to form the conducting hole.

7. The display device according to claim 6, wherein the maximum recess depth of the edge of the display layer in the prescribed direction is the first width.

8. The display device according to claim 1, wherein the display layer is driven by the driving circuit layer and displays merely a single color in the peripheral region.

9. The display device according to claim 1, wherein the opposite electrode layer has a protruding portion that is tongue-shaped and protrudes from an edge of the display layer toward the conducting pad, and the protruding portion and the driving circuit layer are electrically connected through another conducting structure.

10. A display device, comprising:
a driving circuit substrate, comprising a first substrate and a driving circuit layer disposed on the first substrate, wherein the driving circuit layer comprises a display region, a common voltage region, and a conducting pad, the common voltage region is disposed at a periphery of the display region, and the conducting pad is located on the common voltage region and electrically connected to the common voltage region;
a display layer, disposed on the driving circuit substrate;
an opposite substrate, comprising a second substrate and an opposite electrode layer disposed on the second substrate, wherein the display layer is located between the opposite electrode layer and the driving circuit layer; and
a conductive member, connected between the conducting pad and the opposite electrode layer.

11. The display device according to claim 10, wherein the display layer exposes the conducting pad and surrounds the conductive member.

12. The display device according to claim 10, further comprising a protective insulating layer, the conducting pad comprising a metal conductive layer and a pad conductive layer, and the protective insulating layer being disposed between the metal conductive layer and the pad conductive layer.
